(19) United States
(12) Patent Application Publication
(10) Pub. No.: US 2010/0253398 A1
(43) Pub. Date: Oct. 7, 2010

(54) Fully Differential Single-Stage Frequency Divider Having 50% Duty Cycle

(75) Inventor: Utku Seckin, Istanbul (TR)

Correspondence Address: Smith Frohwein Tempel Greenlee Blaha LLC, Two Ravinia Drive, Suite 700, Atlanta, GA, 30346, US

(73) Assignee: Skyworks Solutions, Inc., Woburn, MA (US)

(21) Appl. No.: 12/417,676

(22) Filed: Apr. 3, 2009

(51) Int. Cl. H03B 19/06

(52) U.S. Cl. 327/118; 327/117

(57) ABSTRACT

A fully differential frequency divider includes a first fully differential single-stage latch circuit configured to receive an input signal and provide a corresponding output signal upon transition of a clock signal, the output signal corresponding to an in-phase portion of a communication signal, and a second fully differential single-stage latch circuit coupled to the first fully differential single-stage latch circuit, the second fully differential single-stage latch circuit configured to provide a corresponding output signal upon transition of the clock signal. The second fully differential single-stage latch circuit is also configured to receive as an input signal the output signal of the first fully differential single-stage latch circuit, the output signal of the second fully differential single-stage latch circuit corresponding to a quadrature-phase portion of the communication signal, where the output signal of the second fully differential single-stage latch circuit is provided as the input signal to the first fully differential single-stage latch circuit.

### BACKGROUND

A frequency divider is an electronic circuit that converts a signal having a first frequency to a signal having a second frequency. The second frequency is typically an integer or non-integer fraction of the first frequency. Such frequency dividers are useful in applications that demand a high degree of voltage level signal swing and good linearity performance at GHz operation frequencies.

There are various types of frequency dividers that are widely used. Existing complementary metal oxide semiconductor (CMOS) dividers such as clocked-CMOS (C²MOS) and true single-phase clocked logic (TSPC) dividers provide rail-to-rail voltage swing but they both have only single-ended outputs. Current-Mode-Logic (CML) frequency divider topologies are fully-differential and can operate at high frequencies; however, the output swing is limited to a certain fraction of the available supply voltage. A type of frequency divider, known as a “Razavi” divider, provides rail-to-rail voltage swing, is high-speed and provides a differential output, but only provides an output having a 25% duty cycle instead of the 50% duty cycle, which many applications require.

Therefore, it would be desirable to have a frequency divider that overcomes these limitations.

### SUMMARY

Embodiments of a fully differential frequency divider include a first fully differential single-stage latch circuit configured to receive an input signal and provide a corresponding output signal upon transition of a clock signal, the output signal corresponding to an in-phase portion of a communication signal, and a second fully differential single-stage latch circuit coupled to the first fully differential single-stage latch circuit, the second fully differential single-stage latch circuit configured to provide a corresponding output signal upon transition of the clock signal, the second fully differential single-stage latch circuit also configured to receive as an input signal the output signal of the first fully differential single-stage latch circuit, the output signal of the second fully differential single-stage latch circuit corresponding to a quadrature-phase portion of the communication signal, where the output signal of the second fully differential single-stage latch circuit is provided as the input signal to the first fully differential single-stage latch circuit.

Other embodiments are also provided. Other systems, features, and advantages of the invention will be or become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE FIGURES

The invention can be better understood with reference to the following figures. The components within the figures are not necessarily to scale, emphasis instead being placed upon clearly illustrating the principles of the invention. Moreover, in the figures, like reference numerals designate corresponding parts throughout the different views.

FIG. 1 is a block diagram illustrating a simplified portable transceiver.

FIG. 2 is a simplified schematic diagram illustrating an embodiment of the upconverter of FIG. 1 for use in an I/Q modulator.

FIG. 3 is a schematic diagram illustrating an embodiment of a frequency divider of FIG. 2.

FIG. 4 is a schematic diagram of an embodiment of one of the latches of the frequency divider of FIG. 3.

### DETAILED DESCRIPTION

Although described with particular reference to use in a portable communication device, the frequency divider described herein is applicable to any system in which a fully differential frequency divider having a 50% duty cycle is useful. For example, the frequency divider described herein is particularly useful for an upconverter in a transmitter of a portable communication device. As used herein, the term “50% duty cycle” refers to a nominal 50% duty cycle, and includes slight variations in the duty cycle caused by, for example, process, temperature, manufacturing, and other variations.

The frequency divider comprises a single-stage, fully differential, CMOS topology that reduces power consumption, reduces die area, improves noise performance and improves linearity for the circuitry that is driven by the frequency divider. The frequency divider operates at high speed, provides a rail-to-rail voltage swing, exhibits a 50% duty cycle, and provides fully differential input and output, thus providing I and Q outputs that are inherently 90 degrees offset in phase. Further, while described as being implemented using CMOS technology, the frequency divider described herein is not limited to CMOS, but can also be implemented in other semiconductor device technologies, and in a variety of material systems.

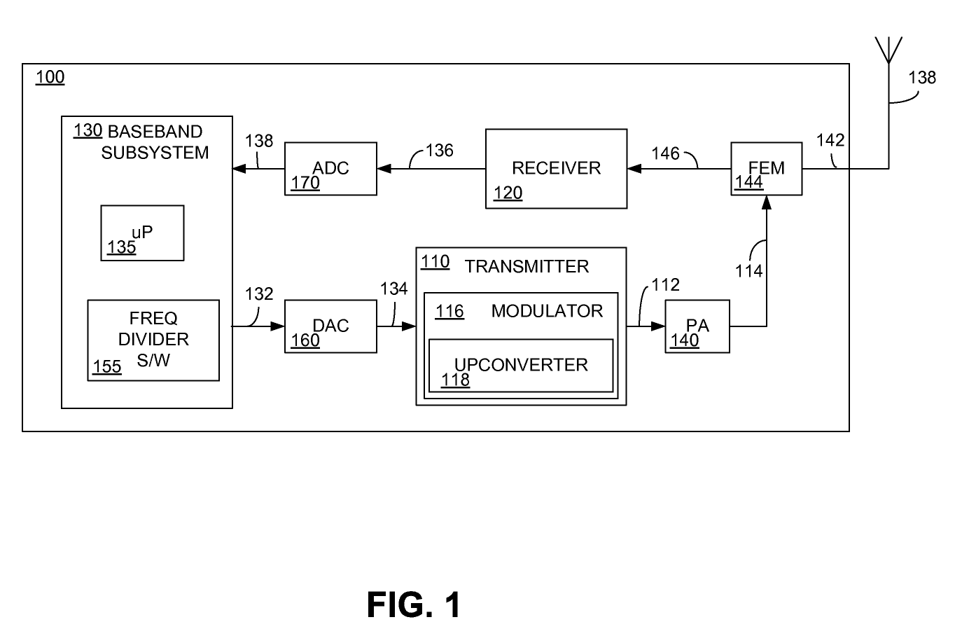

FIG. 1 is a block diagram illustrating a simplified portable transceiver 100. Embodiments of the frequency divider described herein can be implemented in any RF transmitter or RF transceiver, and in this example, are implemented in an RF transmitter associated with a portable transceiver 100. The portable transceiver 100 illustrated in FIG. 1 is intended to be a simplified example and to illustrate one of many possible applications in which the frequency divider can be implemented. One having ordinary skill in the art will understand the operation of a portable transceiver. The portable transceiver 100 includes a transmitter 110, a receiver 120, a baseband subsystem 130, a digital-to-analog converter (DAC) 160 and an analog-to-digital converter (ADC) 170. The transmitter includes a modulator 116 and an upconverter 118. The upconverter 118 can be a subsystem of the modulator 116. In alternative embodiments, the upconverter 118 can be a separate circuit block or circuit element. The upconverter 118 implements embodiments of the frequency divider as described herein.

The transmitter 110 also includes any other functional elements that modulate and upconvert a baseband signal. The receiver 120 includes filter circuitry and downconverter circuitry that enable the recovery of the information signal from the received RF signal. The portable transceiver 100 also includes a power amplifier 140. The output of the transmitter 110 is provided over connection 112 to the power amplifier 140. Depending on the communication methodology, the portable transceiver 100 may also include a power amplifier control element (not shown).

The receiver 120 and the power amplifier 140 are connected to a front-end module 144. The front-end module 144 can be a duplexer, a diplexer, or any element that separates the transmit signal from the receive signal. The front-end module 144 is connected to an antenna 138 over connection 142.

In transmit mode, the output of the power amplifier 140 is provided to the front-end module 144 over connection 114. In receive mode, the front-end module 144 provides a receive signal to the receiver 120 over connection 146.

If portions of the frequency divider are implemented in software, then the baseband subsystem 130 also includes frequency divider software 155 that can be executed by a microprocessor 135, or by another processor, to control the operation of, or portions of the operation of, the frequency divider to be described below.

When transmitting, the baseband transmit signal is provided from the baseband subsystem 130 over connection 132 to the DAC 160. The DAC 160 converts the digital baseband transmit signal to an analog signal that is supplied to the transmitter 110 over connection 134. The modulator 116 and the upconverter 118 modulate and upconvert the analog transmit signal according to the modulation format prescribed by the system in which the portable transceiver 100 is operating. The modulated and upconverted transmit signal is then supplied to the power amplifier 140 over connection 112.

When receiving, the filtered and downconverted receive signal is supplied from the receiver 120 to the ADC 170 over connection 136. The ADC digitizes the analog receive signal and provides the analog baseband receive signal to the baseband subsystem 130 over connection 138. The baseband subsystem 130 recovers the transmitted information.

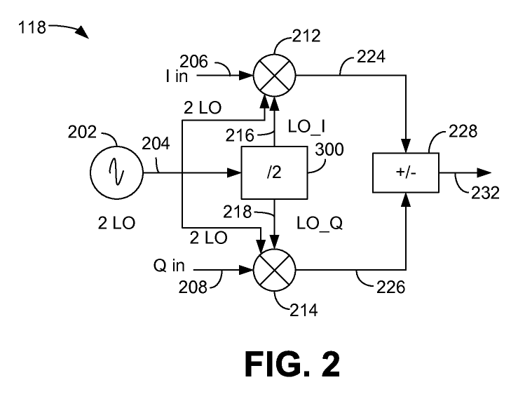

FIG. 2 is a simplified schematic diagram illustrating an embodiment of the upconverter 118 of FIG. 1 for use in an embodiment of an I/Q modulator. The upconverter 118 implements an LO 2LO upconversion methodology in which a local oscillator signal having a frequency that is twice the desired local oscillator frequency is generated and then divided. However, the frequency divider to be described below is applicable in any architecture where it is desirable to divide an input signal by a factor of two.

The upconverter 118 includes an oscillator 202 configured to generate an LO signal on connection 204 that is twice the frequency of the desired LO signal. For example, if the desired LO frequency is a nominal 100 MHz, the signal on connection 204 is nominally 200 MHz. The upconverter 118 also includes a mixer core 212 and a mixer core 214. The mixer cores 212 and 214 are arranged to operate on the quadrature signals I and Q. In an example, the in-phase signal, I_in, is supplied over connection 206 to the mixer core 212 and the quadrature-phase input signal, Q_in, is supplied over connection 208 to the mixer core 214.

The 2LO signal on connection 204 is supplied to the mixer cores 212 and 214, and is also supplied to a frequency divider 300. In an embodiment, the frequency divider 300 is a quadrature divider having a fully differential, single-stage architecture, which operates at a 50% duty cycle.

The frequency divider 300 divides the 2LO signal on connection 204 to a nominal value of LO on connections 216 and 218. In this example, an LO_I signal is supplied to the mixer core 212 over connection 216 and an LO_Q signal is supplied to the mixer core 214 over connection 218.

The mixer cores 212 and 214 each receive the corresponding LO signal and the 2LO signal. The mixer core 212 upconverts the I_in signal and the mixer core 214 upconverts the Q_in signal with minimal noise and impairments. The upconverted I_in signal is supplied to a combining element 228 over connection 224 and the upconverted Q_in signal is supplied to the combining element 228 over connection 226. The output of the combining element 228 on connection 232 is the output signal that is supplied to the power amplifier 140 (FIG. 1). Either the in-phase signal or the quadrature-phase signal can be chosen either by changing the final combining element operation to addition (or subtraction), or by interchanging the I and Q LO signals without changing the final operation.

The architecture of the upconverter 118 suppresses the noise contribution of the frequency divider 300 that is used to generate the quadrature LO signals, LO_I and LO_Q, and therefore, minimizes transmitter noise and sideband generation. Further, the architecture of the upconverter 118 provides a high level of input isolation between the I and Q inputs for a passive mixer implementation.

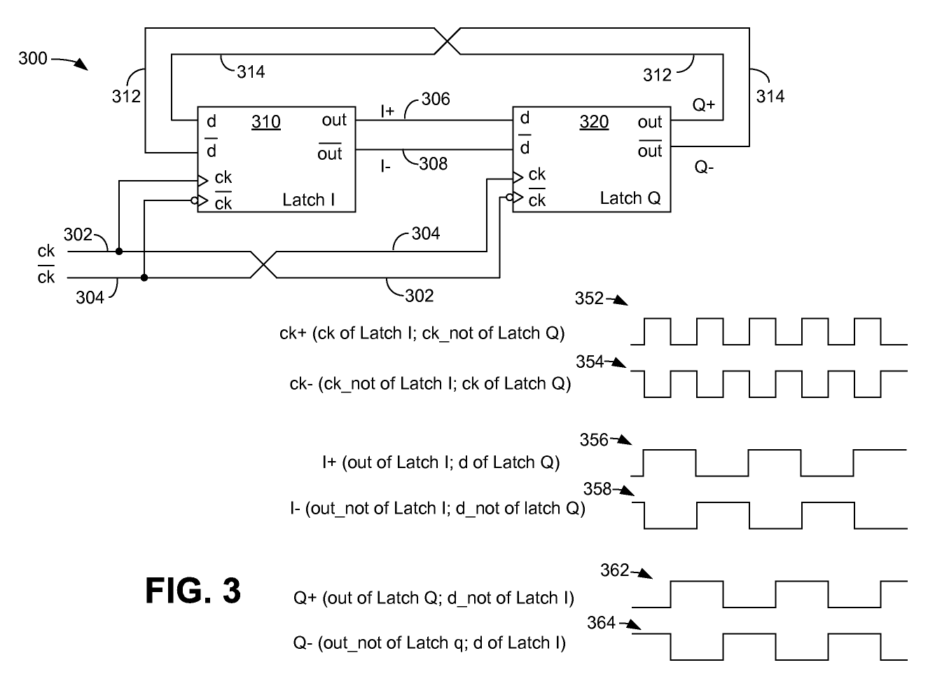

FIG. 3 is a schematic diagram illustrating an embodiment of a frequency divider of FIG. 2. The frequency divider 300 includes a first latch 310 and a second latch 320. In the embodiment shown in FIG. 3, the first latch 310 and the second latch 320 are implemented as “D” flip-flops. In an embodiment in which the divider 300 operates in a fully differential communications system, the first latch 310 processes the differential in-phase (I) signal and the second latch 320 processes the differential quadrature-phase (Q) signal. A clock signal (ck) is provided over connection 302 to the first latch 310 and to the second latch 320. The inverse of the clock signal (ck_not or c̅k̅) is provided over connection 304 to the first latch 310 and to the second latch 320. The output (out) of the first latch 310 on connection 306 forms the positive in-phase signal (I+) and is supplied to the d input of the second latch 320. The inverse of the output (out_not or o̅u̅t̅) is provided from the first latch 310 over connection 308 and forms the negative differential in-phase signal (I−). The signal on connection 308 forms the inverse d input (d_not or d̅) to the second latch 320.

Similarly, the output (out) of the second latch 320 on connection 312 forms the positive differential quadrature-phase signal (Q+) and is supplied as the inverse d input (d_not or d̅) to the first latch 310. The inverse output (out_not or o̅u̅t̅) of the second latch 320 on connection 314 forms the negative differential quadrature-phase signal (Q−) and is supplied as the d input to the first latch 310.

A timing diagram of the signals processed by the divider 300 is shown in FIG. 3. The trace 352 represents the clock signal, ck, while the trace 354 represents the inverse clock signal (ck_not or c̅k̅). As shown, the signals ck and c̅k̅ are 180° out of phase with respect to each other.

The trace 356 represents the positive in-phase signal (I+) output of the first latch 310 on connection 306 which is supplied as the d input of the second latch 320. The trace 358 represents the negative in-phase signal (I−) output of the first latch 310 on connection 308 which is supplied as the d̅ input to the second latch 320.

The trace 362 represents the positive quadrature-phase signal (Q+) output of the second latch 320 on connection 314 and is supplied as the d̅ input of the first latch 310. The signal trace 364 represents the negative differential quadrature-phase signal (Q−) output of the second latch 320 over connection 314 which is supplied as the d input of the first latch 310.

As shown in FIG. 3, the divider 300 implements a fully differential frequency divider. The operation of the frequency divider 300 is as follows. Each latch 310 and 320 passes its d input to its output (out) whenever the clock signal, ck, is logic high. When the clock signal, ck, transitions to logic high, the first latch 310 is in transparent mode and the second latch 320 is in hold mode. Therefore, I+ is switched to Q− and I− is switched to Q+. When the clock signal, ck, transitions to a logic low, I and I− are held, Q+ is switched to I− and Q− is switched to I+. This sequence of operation ensures that there is a 90 degree phase shift between I (I+ and I−) and Q (Q+ and Q−).

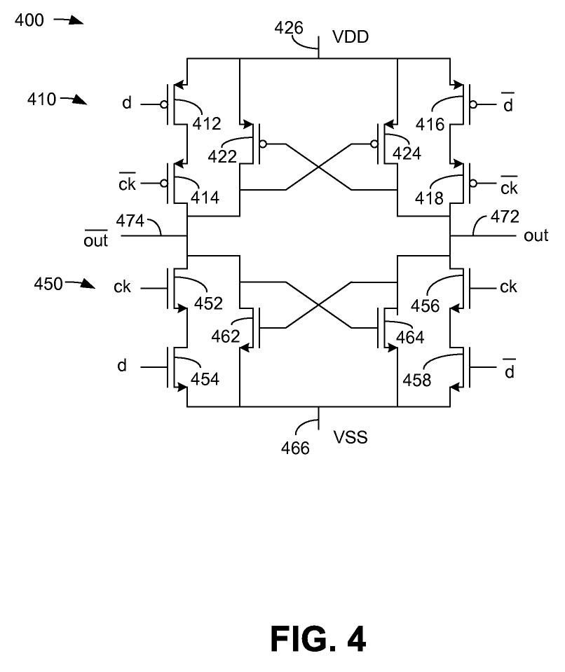

FIG. 4 is a schematic diagram of an embodiment of one of the latches of the frequency divider of FIG. 3. The latch 400 is a fully-differential, high-speed, rail-to-rail CMOS latch constructed using a PMOS section 410 and an NMOS section 450, which form a single-stage latch. The switches illustrated in FIG. 4 are shown for simplicity as field effect transistor (FET) devices. However, other switching device technologies can be used to create the switching elements in FIG. 4. The PMOS section includes switches 412, 414, 416 and 418. The PMOS section 410 also includes an inverter formed by switches 422 and 424, also represented as FET devices.

The NMOS section 450 includes switches 452, 454, 456 and 458. The NMOS section 450 also includes an inverter formed by switches 462 and 464, also represented as FET devices. The switches 412 and 416 are connected to a drain voltage source, VDD, over connection 426 and the switches 454 and 458 are connected to a source voltage, VSS, on connection 466. The d input signal is supplied to the gate terminal of the switch 412 and the d̅ signal is supplied to the gate terminal of the switch 416. The c̅k̅ signal is supplied to the gate terminal of the switch 414 and the switch 418.

The d input signal is supplied to the gate terminal of switch 454 and the d̅ signal is supplied to the gate terminal of the switch 458. The ck signal is supplied to the gate terminal of the switch 452 and to the gate terminal of the switch 456. The output signal, out, is provided over connection 472 and the inverse output signal, o̅u̅t̅, is provided over connection 474.

The latch 400 represents one of the latches 310 or 320 of FIG. 3. To implement the frequency divider 300, two of the latches 400 shown in FIG. 4 would be connected as shown in FIG. 3.

In the transparent mode, the clock signal, ck, is high and the d input overwrites the output, out, through the switches 412, 414, 416, 418, 452, 454, 456 and 458. When the clock signal, ck, transitions to a logic low state, the output is held at its previous value by the inverters formed by switches 422, 424, 462 and 464. In this manner, the latch 400 provides a 50% duty cycle when generating the output signals, out and o̅u̅t̅, from the clock signal, ck, in a single-stage architecture, thereby providing a rail-to-rail voltage swing between the voltages VDD and VSS, and minimizing power consumption, minimizing die area, and generating minimal noise.

The relative size, and therefore, the switching performance, of the switch devices is important, as the switches 422, 424, 462 and 464 should be sufficiently large to have a certain gain in the divider to ensure correct operation. The switches 412, 414, 416 and 418 should be fabricated to provide sufficient current such that they can overwrite the value of the inverter formed by the switches 422 and 424. Similarly, the switches 452, 454, 456 and 458 should be fabricated to provide sufficient current such that they can overwrite the value of the inverter formed by the switches 462 and 464. This ensures that the d input overwrites the output when the latch is in transparent mode. A tradeoff in selecting the size of the switches is that as the size of the devices increases, so does the switching speed. However, a larger device presents a larger load to any associated circuitry. Therefore, careful selection of the switch devices will balance device size and switching speed.

Similar functionality to that described above can be achieved with fewer switches at the expense of reliability or slower output swing.

As an alternative implementation, the inverter formed by switches 422 and 424 or the inverter formed by switches 462 and 464 may be removed, while substantially preserving the above-described functionality. However, the switch devices forming the remaining inverter must be increased in size to have similar gain. Moreover, eliminating one of the inverters causes one of the outputs to be in high impedance mode during hold mode.

In yet another alternative implementation, the switches 412, 414, 416 and 418, along with the inverter formed by switches 462 and 464 (or the switches 452, 454, 456 and 458 along with the inverter formed by the switches 422 and 424) could be removed. However, this alternative decreases the rise/fall time of the output significantly, although it still achieves the same functionality.

While various embodiments of the invention have been described, it will be apparent to those of ordinary skill in the art that many more embodiments and implementations are possible that are within the scope of the invention. For example, the invention is not limited to a specific semiconductor material system.

What is claimed is:

1. A fully differential, frequency divider, comprising:
a first fully differential single-stage latch circuit configured to receive an input signal and provide a corresponding output signal upon transition of a clock signal, the output signal corresponding to an in-phase portion of a communication signal; and
a second fully differential single-stage latch circuit coupled to the first fully differential single-stage latch circuit, the second fully differential single-stage latch circuit configured to provide a corresponding output signal upon transition of the clock signal, the second fully differential single-stage latch circuit also configured to receive as an input signal the output signal of the first fully differential single-stage latch circuit, the output signal of the second fully differential single-stage latch circuit corresponding to a quadrature-phase portion of the communication signal, where the output signal of the second fully differential single-stage latch circuit is provided as the input signal to the first fully differential single-stage latch circuit.

2. The frequency divider of claim 1, in which each latch circuit further comprises:
a first plurality of p-type metal oxide semiconductor (PMOS) switches coupled to a first voltage and cross coupled to a first inverter; and
a first plurality of n-type metal oxide semiconductor (NMOS) switches coupled to a second voltage and cross coupled to a second inverter, wherein the first plurality of PMOS switches and the first plurality of NMOS switches provide a fully differential output that alternates between the first voltage and the second voltage following a 50% duty cycle.

3. The frequency divider of claim 2, wherein:
the first plurality of p-type metal oxide semiconductor (PMOS) switches provide sufficient current to overwrite a value of the first inverter when each latch is in a transparent mode; and
the first plurality of n-type metal oxide semiconductor (NMOS) switches provide sufficient current to overwrite a value of the second inverter when each latch is in the transparent mode.

4. A CMOS latch circuit, comprising:
a first plurality of p-type metal oxide semiconductor (PMOS) switches coupled to a first voltage and cross coupled to a first inverter; and
a first plurality of n-type metal oxide semiconductor (NMOS) switches coupled to a second voltage and cross coupled to a second inverter, wherein the first plurality of PMOS switches and the first plurality of NMOS switches provide a fully differential output that alternates between the first voltage and the second voltage following a 50% duty cycle.

5. The latch circuit of claim 4, wherein:
the first plurality of p-type metal oxide semiconductor (PMOS) switches provide sufficient current to overwrite a value of the first inverter when the latch circuit is in a transparent mode; and
the first plurality of n-type metal oxide semiconductor (NMOS) switches provide sufficient current to overwrite a value of the second inverter when the latch circuit is in the transparent mode.
